(19) United States
(12) Patent Application Publication
(10) Pub. No.: US 2013/0027136 A1
(43) Pub. Date: Jan. 31, 2013

(54) VARIABLE GAIN AMPLIFIER SYSTEM AND METHOD

(71) Applicants: Peter Ossieur, Bruges (BE); Anil Jain, Cork City (IE); Paul D. Townsend, County Cork (IE)

(72) Inventors: Peter Ossieur, Bruges (BE); Anil Jain, Cork City (IE); Paul D. Townsend, County Cork (IE)

(73) Assignee: University College Cork - National University of Ireland, Cork City (IE)

(21) Appl. No.: 13/558,897

(22) Filed: Jul. 26, 2012

Related U.S. Application Data
(60) Provisional application No. 61/512,509, filed on Jul. 28, 2011.

(51) Int. Cl. H03G 3/10

(52) U.S. Cl. 330/279

(57) ABSTRACT

The invention provides a variable gain amplifier system for use in a burst mode receiver, said system comprising an amplifier adapted to amplify a signal; a gain control module; a dc offset compensation module adapted to derive a compensation signal as a function of the amplifier gain. Compared to existing methods for dc offset compensation in variable gain amplifier, the system and method for dc offset compensation allows fast adjustment of rapidly changing dc offsets that occur in applications where the gain of the variable gain amplifier is adjusted rapidly.

This application claims the benefit of U.S. Provisional Application No. 61/512,509, filed Jul. 28, 2011, which is incorporated by reference as if fully set forth.

### FIELD OF INVENTION

The invention relates to a variable gain amplifier with fast dc offset compensation. In particular the invention relates to the field of analogue electronic circuits, more specifically variable gain amplifiers, especially for use in applications, such as optical burst mode receivers, that require fast adjustments of the gain, while maintaining small dc offsets.

### BACKGROUND

A variable gain amplifier is a specific type of electrical amplifier whose gain can be adjusted using a specific control signal (V_{control}). Such variable gain amplifiers are widely used in for example receiver chains that use automatic gain control, for example optical receiver for fibre-optic applications, or in the receiver for wireless applications.

Any type of electrical amplifier exhibits an unwanted dc offset, meaning that the output of the amplifier is non-zero even when its input is zero. The source of such dc offset is usually due to unavoidable component (transistors, resistors) mismatches. The dc offset is usually undesirable, for example in an optical receiver it may degrade the receiver sensitivity (the smallest possible signal that can be detected with a given quality e.g. error rate). It can be compensated using for example a feedback loop, which measures the dc offset at the output of the amplifier, and adds a correction to the input of the amplifier such that the dc offset at the output of the amplifier is driven to zero, see FIG. 1.

In the specific case of a variable gain amplifier, the dc offset usually depends on the gain setting. Any dc offset compensation mechanism must hence adjust itself to remove the dc offset of the variable gain amplifier whenever a gain change occurs. A feedback loop as described above can achieve this. As the feedback loop needs to be stable, it is necessary slow, and hence will only be able to compensate for slowly changing dc offsets.

In some applications however, such as burst-mode receivers, it is necessary to change the gain of the variable gain amplifier quickly (for example, within a few tens of nanoseconds at the start of a burst). In this case, the dc offset will also change rapidly. Hence, any dc offset compensation mechanism must now also quickly compensate for the new dc offsets after a gain change.

The classical method of dc offset compensation relies on a feedback loop which measures the dc offset at the output of the variable gain amplifier. It then provides a correction to the input of the variable gain amplifier such that the dc offset at the output is driven to zero. As mentioned above, this is inherently slow due to the requirement of having a stable loop.

For many different types of applications, variable gain amplifiers with low dc offsets are a desirable circuit. This for example includes optical receivers, where unwanted dc offsets may result in increased error rates, or even worse saturation of the receiver. Clearly, for proper operation of the receiver, these unwanted dc offsets must be compensated.

Classical methods of removing dc offsets in a variable gain amplifier consist of closing a feedback loop across a fully differential, variable gain amplifier. This feedback loop monitors the difference between the average values of both output phases of the differential amplifier, or the peak values of both output phases, or some other derived signal that is representative of the dc offset. The feedback loop then adds a signal that is derived (through amplification, integration, differentiation or any combination of these) from the aforementioned difference to the input signals of the differential amplifier, in such a way that the aforementioned output is driven to zero.

While this feedback mechanism allows for highly precise compensation of dc offsets, due to its feedback nature it cannot track rapidly changing dc offsets. Such rapidly dc offsets can occur for example when the gain of the variable gain amplifier needs to be adjusted rapidly. Indeed typically the dc offset of a variable gain amplifier is highly dependent upon its gain setting. If the gain of the variable gain amplifier is rapidly adjusted, then the dc offset will change rapidly as well. A mechanism that rapidly adjusts the dc offset is thus required.

A publication by H.-M. Bae et. al., “An MLSE Receiver for Electronic Dispersion Compensation of OC-192 Fiber Links”, IEEE Journal of Solid-State Circuits, vol. 41, pp. 2541-2554, December 2006 describes the concept of a variable gain amplifier for an optical receiver that includes dc-offset compensation. However the problem with the dc-offset compensation method described in this publication only allows compensation of slowly varying dc-offsets. In many applications however the gain of a variable gain amplifier needs to be changed quickly. As the dc-offset of a variable gain amplifier depends on its gain, it is hence required that any dc-offsets can be compensated quickly, which cannot be done using the method described in the above publication. In addition the dc-offset compensation method described in the above publication relies on the usage of at least two large external capacitors which increases the external component count and associated cost.

It is therefore an object of the invention to provide a variable gain amplifier with fast dc offset compensation to overcome at least one of the above mentioned problems.

### SUMMARY

According to the invention there is provided a variable gain amplifier system for use in a burst mode receiver, said system comprising:

an amplifier adapted to amplify a signal;

a gain control module; and

a dc offset compensation module adapted to derive a compensation signal as a function of the amplifier gain.

The present invention allows for compensation of dc-offsets without any additional external components such as capacitors. Compared to existing systems and methods for dc offset compensation in variable gain amplifier, this system and method for dc offset compensation allows fast adjustment of rapidly changing dc offsets that occur in applications where the gain of the variable gain amplifier is adjusted rapidly. A further advantage of the dc offset compensation system and method is that it does not require any large (e.g. external to the chip) capacitors, thus saving on the amount of required components.

In one embodiment the gain control module and the dc offset compensation module share a control signal, said shared control signal is selected to control the gain of the amplifier.

In one embodiment the fast dc offset compensation is based upon calibration of the dc offset using programmable current (or voltage) sources, fractions of which are connected to appropriate node(s) of the variable gain amplifier.

In one embodiment the fractions are made dependent upon the same signal that controls the gain of the variable gain amplifier.

In one embodiment a first current (or voltage) source is provided with programmable value and sign. A fraction of this current (or voltage), the size of which depends on the signal that controls the gain of the variable gain amplifier, can be connected to a first appropriate node of the variable gain amplifier.

In one embodiment a second current (or voltage) is provided with programmable value and sign. A fraction of this current (or voltage), the size of which depends on the signal that controls the gain of the variable gain amplifier, is connected to the first or a second appropriate node of the variable gain amplifier.

In another embodiment of the invention there is provided a method of controlling a variable gain amplifier system for use in a burst mode receiver, said method comprising:

amplifying a signal using an amplifier to provide an amplifier gain to the signal controlled by a gain control module;

deriving a compensation signal as a function of the amplifier gain using a DC offset compensation module.

In a further embodiment there is provided a receiver for use in a communications network, the receiver comprising a variable gain amplifier comprising:

an amplifier adapted to amplify a signal;

a gain control module; and

a dc offset compensation module adapted to derive a compensation signal as a function of the amplifier gain.

In another embodiment there is provided a burst mode optical receiver comprising a variable gain amplifier comprising:

an amplifier adapted to amplify a signal;

a gain control module; and

a dc offset compensation module adapted to derive a compensation signal as a function of the amplifier gain.

There is also provided a computer program comprising program instructions for causing a computer program to carry out the above method which may be embodied on a record medium, carrier signal or read-only memory.

### BRIEF DESCRIPTION OF THE DRAWINGS

The invention will be more clearly understood from the following description of an embodiment thereof, given by way of example only, with reference to the accompanying drawings, in which:—

FIG. 1 illustrates a conventional dc offset compensation for variable gain amplifier;

FIG. 2 illustrates a principle of fast offset compensation, according to one embodiment of the invention;

FIG. 3 illustrates an implementation of a variable gain amplifier with fast dc offset compensation, according to one embodiment of the invention;

FIG. 4 illustrates a low gain and high gain dc offset compensation currents as a function of V_{control};

FIG. 5 illustrates a first implementation of the dc offset compensation current source; and

FIG. 6 illustrates a second implementation of the dc offset compensation current source.

### DETAILED DESCRIPTION OF THE DRAWINGS

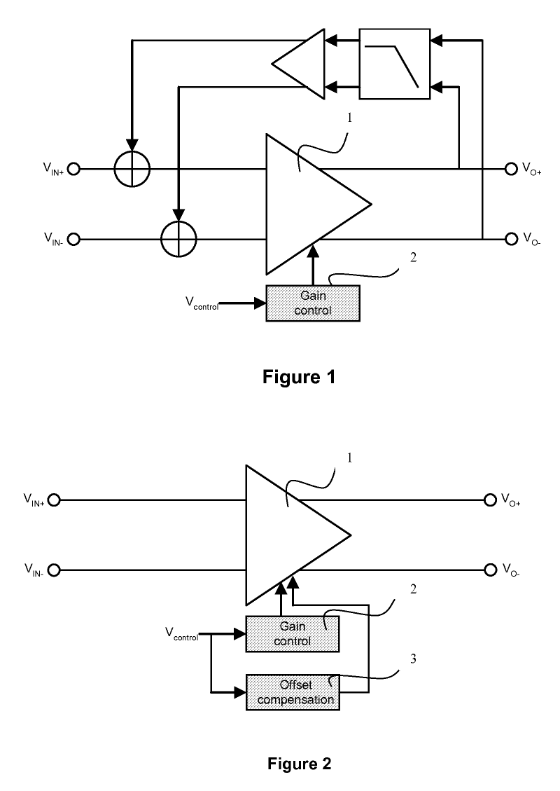

FIG. 2 illustrates a principle of fast offset compensation, according to one embodiment of the invention. FIG. 2 illustrates a variable gain amplifier system comprising an amplifier 1 adapted to amplify a signal; a gain control module 2; and a dc offset compensation module 3 adapted to derive a compensation signal as a function of the amplifier 1. If the dc offset behaviour as a function of the gain of the variable gain amplifier is known, then it is possible to derive a compensation signal as a function of the gain of the variable gain amplifier that, when added to a signal path, compensates for the dc offset. Note that there are now no inherent speed limitations due to the usage of feedback loops across the amplifier. The speed of the dc offset compensation is now rather dependent on the response time of the “offset compensation” block shown in FIG. 2. The offset compensation module 3 can be implemented orders of magnitude faster than a conventional amplifier as shown in FIG. 1, as this offset compensation module does not contain any feedback loops. The gain control module 2 and the dc offset compensation module 3 share a control signal, wherein the shared control signal is selected to control the gain of the amplifier. The sharing of the control signal greatly simplifies the architecture of the amplifier system.

The fast dc offset compensation is based precisely upon using offset compensation block or module 3. More specifically, the offset compensation block is based upon calibration of the dc offset using programmable current (or voltage) sources, fractions of which are connected to appropriate node(s) of the variable gain amplifier. The fractions are made dependant upon the same signal that controls the gain of the variable gain amplifier, see FIG. 2.

More specifically, the fast dc offset compensation of the variable gain amplifier is realized in a number of different implementations, for example:

A first current (or voltage) source with programmable value and sign. A fraction of this current (or voltage), the size of which depends on the signal that controls the gain of the variable gain amplifier, is connected to a first appropriate node of the variable gain amplifier.

A second current (or voltage) source with programmable value and sign. A fraction of this current (or voltage), the size of which depends on the signal that controls the gain of the variable gain amplifier, is connected to the first or a second appropriate node of the variable gain amplifier.

As an example, the first current (or voltage) source can be adjusted to remove the dc offset of the variable gain amplifier when it is set in its minimum gain. The second current (or voltage) source can be adjusted to remove the dc offset of the variable gain amplifier when it is set in its maximum gain. For any gain setting between the minimum and maximum gain, an appropriate combination of both current (or voltage) sources is used to remove the dc offset. If this combination is chosen in such a way that it depends on the signal that controls the gain of the variable gain amplifier, can be derived quickly (on the same timescale that it takes to adjust the gain) and minimizes the dc offset for gain settings between minimum and maximum gain. This mechanism will compensate the dc offset quickly following any rapid gain changes.

The required setting of the first current (or voltage) source can be found (calibrated) by setting the variable gain amplifier to its minimum gain, setting the signal input to zero, and adjusting this first current (or voltage) source such that the measured dc offset at the output of the variable gain amplifier equals zero. Similarly, the setting of the second current (or voltage) source can be found (calibrated) for the maximum gain setting.

For example, assuming a perfectly linear variable gain amplifier:

V_{OUT}=A_{V}V_{IN}+V_{OFF} (1)

in which V_{OUT} is the wanted output signal of the amplifier, V_{IN} the input signal, A_{V} its gain and V_{OFF} the unwanted dc offset. Assuming that the unwanted dc offset depends linearly on the gain one can write:

V_{OFF}=V_{OFF,0}+A_{V}V_{OFF,A}. (2)

One can now add a compensation signal to (1) based on two signal sources, such that the unwanted dc offset is removed for any gain setting A_{V} between 0 and A_{VMAX}:

$${V}_{COMP} = - ( 1 - \frac{{A}_{V}}{{A}_{V , MAX}} ) {V}_{OFF , 0} - \frac{{A}_{V}}{{A}_{V , MAX}} ( {V}_{OFF , 0} + {A}_{MAX} {V}_{OFF , A} ) . \qquad ( 3 )$$

It will be appreciated one can obtain the first signal source (V_{OFF,0}) by setting the gain equal to its minimum (0 in this specific case), and measuring the output for zero signal input. The second signal source (V_{OFF,0}+A_{VMAX}V_{OFF,A}) can be found by setting the gain to maximum and again measuring the output of the amplifier for zero input.

Equation (3) then describes how to combine both sources based on the gain setting to achieve a zero offset across all possible values of the gain A_{V} between 0 and A_{VMAX}. As will be shown hereafter, implementations exist whereby offset compensation sources can be combined in such a manner that the dc offset is adjusted as fast as the gain is adjusted.

It will be appreciated that the variable gain amplifier with fast compensation of dc offsets, according to the invention, has a wide range of applications. For example, it can be used as a gain block of a burst-mode optical receiver, in which the gain needs to be adjusted quickly from one incoming burst to the next. Such a burst-mode optical receiver, and especially a linear version, finds its application in the upstream channel of today's fibre-to-the-home (FTTH) applications. It can have similar applications in wireless applications that employ time division multiple access (TDMA).

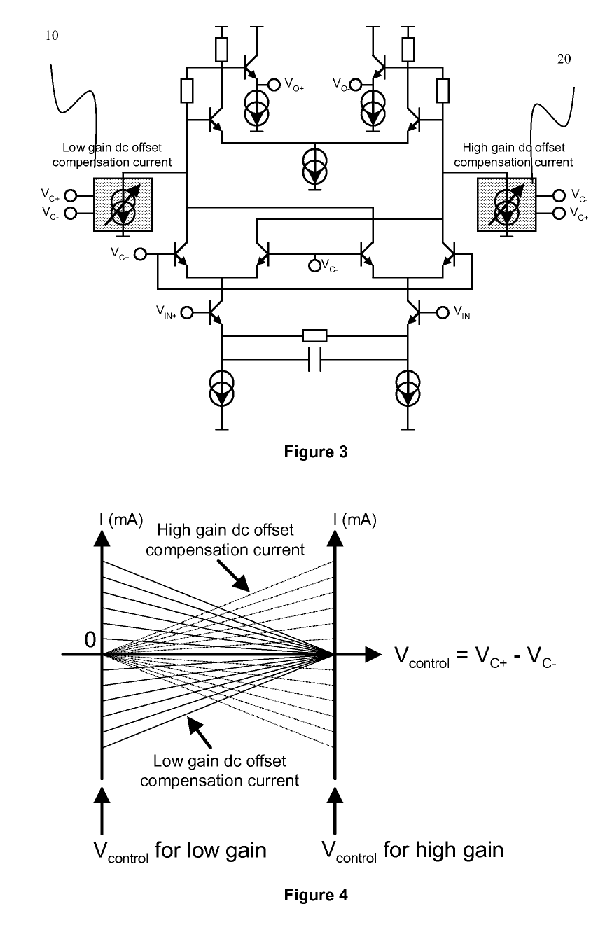

A variable gain amplifier is shown in FIG. 3 incorporating the invention is shown. The gain of the amplifier can be adjusted by adjusting the differential control signal V_{CONTROL}=V_{C+}−V_{C-}. As described previously, dc offset compensation can be provided by two programmable current sources 10 and 20, labeled in FIG. 3 as a “Low gain dc offset compensation current” and the “High gain dc offset compensation current”.

FIG. 4 shows how both dc offset compensation currents behave as a function of the control voltage V_{control}. Clearly for low gain (V_{control}=0V) only the low gain dc offset compensation current 10 provides dc offset compensation. For high gain only the high gain dc offset compensation current 20 provides the dc offset compensation. A linear combination of both currents is used for any gain value between the lowest and highest gain setting.

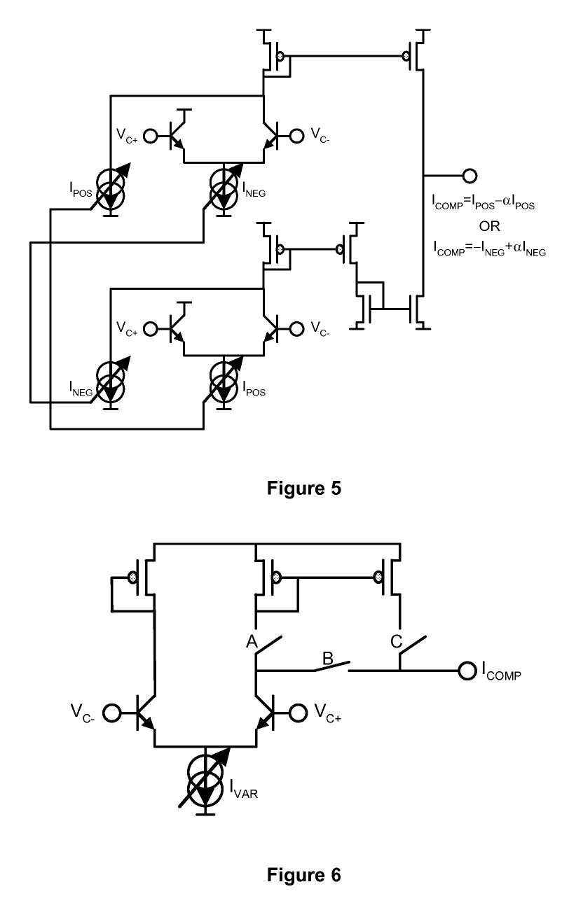

FIG. 5 shows an example implementation of the Compensation Current circuits in FIG. 3 such that they can be controlled as indicated in FIG. 4. The current source is constructed from four variable current sources (for example D/A converters): twice I_{POS} and twice I_{NEG}. If the dc offset compensation current needs to be positive, I_{NEG} is set to zero, and vice versa. The compensating current is made adjustable using two differential pairs, which are controlled by the same differential control signal (V_{C+}−V_{C-}) as the control signals for the gain adjustment in FIG. 3.

FIG. 6 shows a second implementation of the Compensation Current circuits in FIG. 3 such that they can be controlled as indicated in FIG. 4. The variable current source (D/A converter) sets the current through the differential pair. The differential signal (V_{C+}−V_{C-}), the same signal used to control the gain of the Amplifier, controls the amount of current flowing through the output branch which is connected to the output by switches. Depending upon the configuration of switches the circuit acts as a Current Source or Sink. When B and C are switched to A and Tout respectively, the circuit acts like a Current Source and when B is switched to Iout, A and C are open terminals, the circuit acts like a Current Sink.

The exact value of the dc offset compensation current can be derived from the calibration procedure as follows:

Put the amplifier into its low gain mode.

Short the inputs of the amplifier together.

Measure the output dc offset.

From the sign of the output dc offset, determine whether the “low gain dc offset compensation current” should be Sinked or Sourced.

Adjust the variable current source till the output dc offset is zero. This can be done using for example successive approximation fashion, or using a binary search algorithm.

Follow the same steps for the high gain offset compensation current.

It is important to note that the speed of the dc offset compensation mechanism is only limited by the speed of the current mirrors and differential pairs in FIG. 5, which can be orders of magnitude faster compared to conventional feedback dc offset compensation loops. There is no inherent speed limitation due to stability concerns as when feedback dc offset compensation loops are used. The disadvantage is that the dc offset compensation can be less accurate. For example, whenever the temperature of the circuit starts to drift, the dc offset can start to increase again. This can be easily overcome in for example TDMA (time division multiple access) networks in which the traffic can be interrupted, by regularly performing the described calibration algorithm and updating the D/A converter settings to adjust for the new dc offsets.

The embodiments in the invention described with reference to the drawings comprise a computer apparatus and/or processes performed in a computer apparatus. However, the invention also extends to computer programs, particularly computer programs stored on or in a carrier adapted to bring the invention into practice. The program may be in the form of source code, object code, or a code intermediate source and object code, such as in partially compiled form or in any other form suitable for use in the implementation of the method according to the invention. The carrier may comprise a storage medium such as ROM, e.g. CD ROM, or magnetic recording medium, e.g. a floppy disk or hard disk. The carrier may be an electrical or optical signal which may be transmitted via an electrical or an optical cable or by radio or other means.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

What is claimed is:

1. A variable gain amplifier system for use in a burst mode receiver, said system comprising:
an amplifier adapted to amplify a signal;
a gain control module; and
a dc offset compensation module adapted to derive a compensation signal as a function of the amplifier gain.

2. The amplifier system of claim 1 wherein the gain control module and the dc offset compensation module share a control signal, said shared control signal is selected to control the gain of the amplifier.

3. The amplifier system of claim 1 comprising at least one programmable current source adapted to provide dc offset compensation based upon calibration of the dc offset, fractions of which are connected to an appropriate node of the amplifier.

4. The amplifier system of claim 3 wherein the fractions are made dependent upon a shared control signal that controls the gain of the variable gain amplifier.

5. The amplifier system of claim 1 wherein the dc offset compensation module comprises a first current source configured with a programmable value and sign.

6. The amplifier system of claim of claim 1 comprising a first current source configured with a programmable value and sign wherein a fraction of the current can be connected to a first appropriate node of the variable gain amplifier.

7. The amplifier system of claim 6 wherein the size of the fraction is dependent on a control signal that controls the gain of the variable gain amplifier.

8. The amplifier system of claim 1 comprising a second current source configured with a programmable value and sign wherein a fraction of the current can be connected to the first or a second appropriate node of the variable gain amplifier.

9. A receiver for use in a communications network, the receiver comprising a variable gain amplifier, said variable gain amplifier comprising:
an amplifier adapted to amplify a signal;
a gain control module; and
a dc offset compensation module adapted to derive a compensation signal as a function of the amplifier gain.

10. A burst mode optical receiver comprising a variable gain amplifier, said variable gain amplifier comprising:
an amplifier adapted to amplify a signal;
a gain control module; and
a dc offset compensation module adapted to derive a compensation signal as a function of the amplifier gain.
